(19) United States
(12) Patent Application Publication
(10) Pub. No.: US 2026/0040707 A1
(43) Pub. Date: Feb. 5, 2026

(54) DEEP TRENCH ISOLATION FOR PIXELS IN IMAGE SENSORS

(71) Applicant: Taiwan Semiconductor Manufacturing Company, Ltd., Hsinchu (TW)

(72) Inventors: Tzu Te LIU, New Taipei City (TW); Keng-Ying LIAO, Tainan City (TW); Po-Zen CHEN, Tainan City (TW); Chih Wei SUNG, Kaohsiung (TW); Chien-Chung CHEN, Kaohsiung City (TW); Hsien-Kai TSENG, New Taipei City (TW)

(73) Assignee: Taiwan Semiconductor Manufacturing Company, Ltd., Hsinchu (TW)

(21) Appl. No.: 18/793,261

(22) Filed: Aug. 2, 2024

(51) Int. Cl. H01L 27/146

(52) U.S. Cl. CPC H10F 39/807; H10F 39/014

(57) ABSTRACT

The present disclosure is directed to a semiconductor image sensor structure and a method of forming the structure. The structure includes image sensing pixels with a critical dimension (CD) and separated by deep trench isolations (DTIs) with a high aspect ratio (AR). Sections of the DTIs between adjacent image sensing pixels have a substantially even bottom surface profile in comparison to a bottom surface profile at intersections of the DTIs. The method includes performing an etching process and a coating process to mitigate loading effects. The etching process and the coating process are alternatingly repeated until bottom surfaces of the DTIs are etched into a doped layer under the image sensing pixels to prevent leakage of optically-excited charge carriers between the image sensing pixels.

### BACKGROUND

Semiconductor image sensors are used to sense radiation, such as light. Complementary metal-oxide-semiconductor (CMOS) image sensors and charge-coupled device (CCD) sensors are used in various applications, such as digital camera and mobile phone camera applications. These devices utilize an array of pixels (which may include photodiodes and transistors) in a substrate to sense radiation projected toward the pixels and convert the sensed radiation into electrical signals.

### BRIEF DESCRIPTION OF THE DRAWINGS

Aspects of the present disclosure are best understood from the following detailed description when read with the accompanying figures. It is noted that, in accordance with the common practice in the industry, various features are not drawn to scale. In fact, the dimensions of the various features may be arbitrarily increased or reduced for clarity of illustration and discussion.

FIGS. 1A and 1B are horizontal cross sectional views of a semiconductor image sensor device, according to some embodiments.

FIGS. 2A and 2B are vertical cross sectional views of a semiconductor image sensor device, according to some embodiments.

FIGS. 3A and 3B are flowcharts of a method for forming a structure of semiconductor image sensor device, according to some embodiments.

FIGS. 4A and 7A are top views of an intermediate structure of a semiconductor image sensor device during its manufacturing process, in accordance with some embodiments.

FIGS. 4B-6 and 7B-13 are vertical cross sectional views of intermediate structures of a semiconductor image sensor device during its manufacturing process, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features such that the first and second features are not in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the terms “about” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “about” and “substantially” can refer to a percentage of the values as interpreted by those skilled in relevant art(s) in light of the teachings herein.

A semiconductor image sensing device, such as a complementary metal-oxide-semiconductor (CMOS) image sensor, can include one or more arrays of image sensing pixels to generate images. The image sensing pixels are separated by deep trench isolations (DTIs), which are filled with dielectric materials. Each of the image sensing pixels can include a photodiode to generate charge carriers in response to an incident light. The charge carriers can traverse through a doped layer under the image sensing pixels and then be collected as electrical signals and processed by electronic devices. The doped layer can form a depletion region to prevent charge carriers generated by an image sensing pixel to leak into adjacent image sensing pixels, so that signals provided by the image sensing pixels can be resolved.

With the development of semiconductor fabrication technology, critical dimensions (CDs) of the arrays of image sensing pixels can be scaled down to provide the semiconductor image sensing device with improved performance, such as higher resolution. For example, more image sensing pixels can be packed within a limited sensing area of the semiconductor image sensing device by reducing widths of the image sensing pixels down to micrometer ranges and by reducing widths of the DTIs down to sub-micrometer ranges. In the fabrication process of forming the DTIs with narrower and deeper features (corresponding to higher aspect ratios), etching rates at the bottom surfaces of the DTIs can vary significantly depending on the local geometrical details of the DTIs. This phenomenon is also referred to as a “loading effect.” In particular, bottom surfaces at intersections of the DTIs can have greater CDs than bottom surfaces at sections of the DTIs away from the intersections and can be etched deeper. With the reducing CDs of the image sensing pixels, effects of the higher etching rate at the bottom surfaces at intersections of the DTIs can extend into sections of the DTIs between adjacent image sensing pixels, rendering uneven DTI bottom surfaces. As a result, some portions of the bottom surfaces of the DTIs may not be etched deep enough into the doped layer and light-excited charge carriers between adjacent image sensing pixels can leak in these portions, compromising the resolution of the semiconductor image sensing device.

To overcome the challenges mentioned above, the embodiments described herein are directed to a structure of a semiconductor image sensor device and a method of forming the structure. In some embodiments, the structure can include image sensing pixels with a small CD and separated by DTIs with a high aspect ratio (AR). In some embodiments, sections of the DTIs between adjacent image sensing pixels can have a substantially even bottom surface profile to prevent leakage of optically-excited charge carriers between the image sensing pixels. In some embodiments, the method can include performing an etching process and a coating process to mitigate loading effects. In some embodiments, the etching process and the coating process can be alternatingly repeated until bottom surfaces of the DTIs are etched into a doped layer under the image sensing pixels.

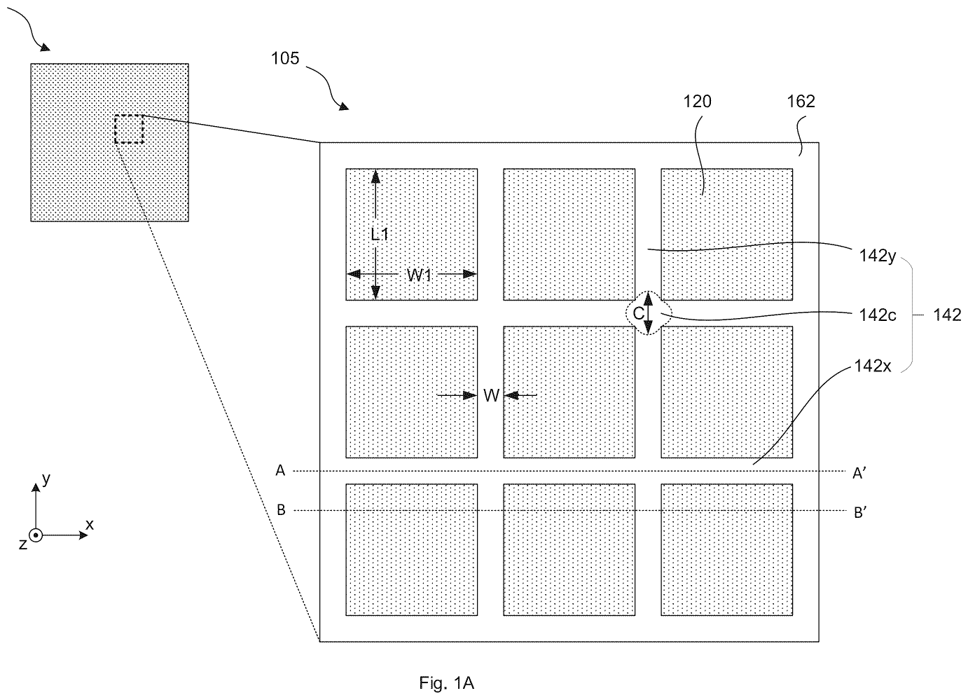

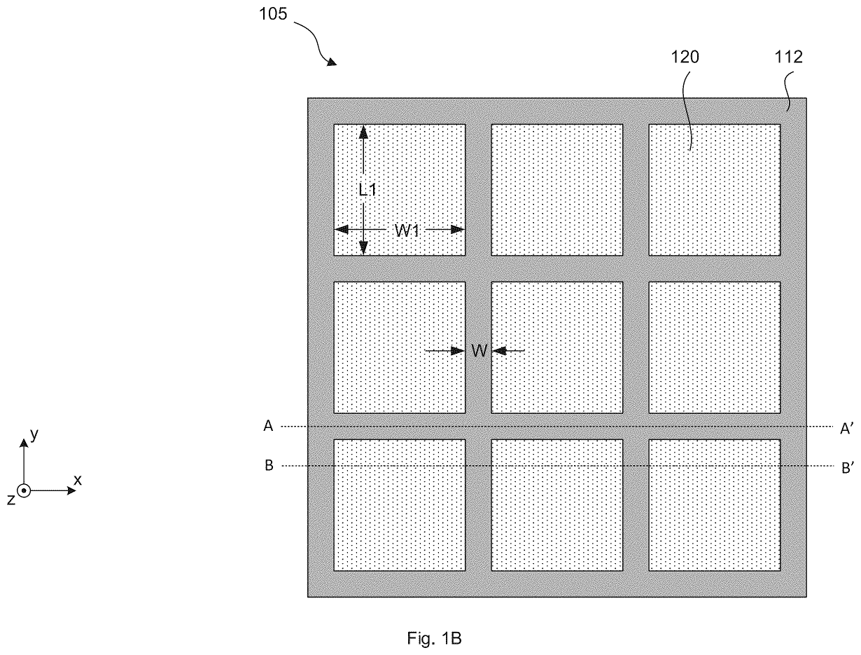

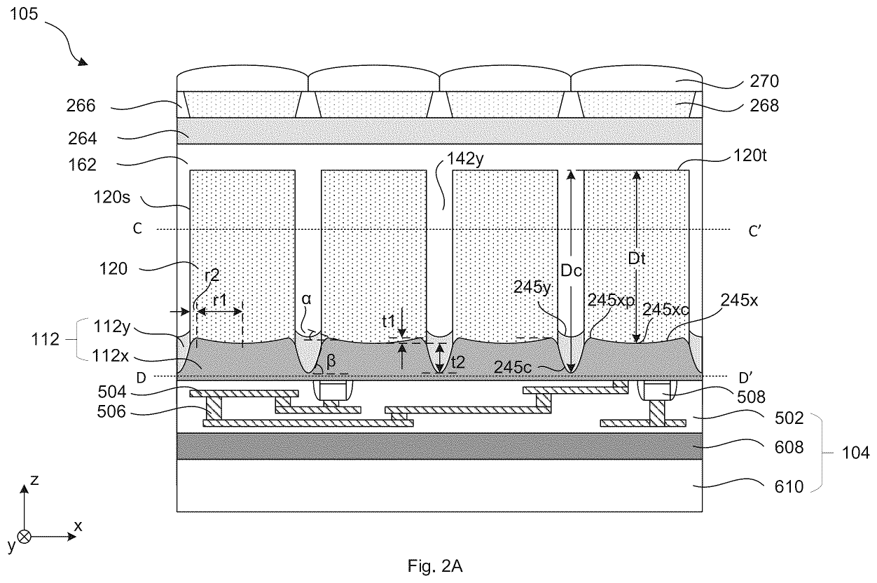

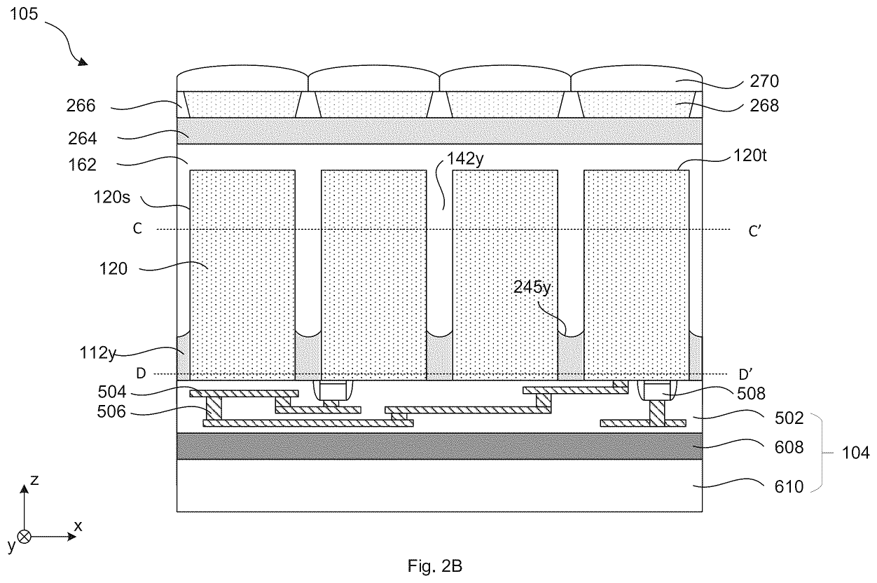

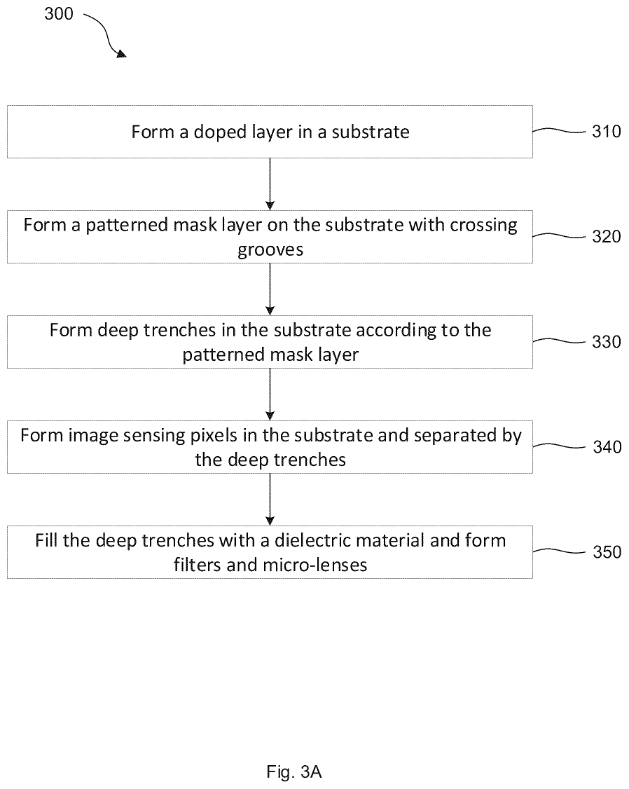

An image sensor device 100 is described with reference to FIGS. 1A to 2B. FIG. 1A illustrates a top view of image sensor device 100, according to some embodiments. FIG. 1A also illustrates a horizontal cross sectional view of a structure 105, which is a magnified portion of image sensor device 100. FIG. 1B illustrates another horizontal cross sectional view of structure 105, according to some embodiments. FIG. 2A illustrates a vertical cross sectional view of structure 105 corresponding to a line A-A′ in FIGS. 1A and 1B, according to some embodiments. FIG. 2B illustrates a cross sectional view of structure 105 corresponding to a line B-B′ in FIGS. 1A and 1B, according to some embodiments. Note that the horizontal cross sectional view illustrated in FIG. 1A corresponds to a line C-C′ in FIGS. 2A and 2B, and the horizontal cross sectional view illustrated in FIG. 1B corresponds to a line D-D′ in FIGS. 2A and 2B.

Referring to FIGS. 1A-2B, structure 105 can include a doped layer 112 and an array of pixels 120 disposed on a substrate 104, with lower portions of array of pixels 120 surrounded by doped layer 112. Substrate 104 can extend along horizontal directions (e.g., x and/or y axes) and have a top surface perpendicular to a vertical direction (e.g., z-axis). Substrate 104 can include a semiconductor material, such as silicon (Si). In some embodiments, substrate 104 can include a crystalline silicon substrate (e.g., Si wafer). In some embodiments, substrate 104 can include (i) an elementary semiconductor, such as silicon or germanium (Ge); (ii) a compound semiconductor including silicon carbide (SiC), gallium arsenide (GaAs), gallium phosphide (GaP), indium phosphide (InP), indium arsenide (InAs), and/or indium antimonide (InSb); (iii) an alloy semiconductor including silicon germanium carbide (SiGeC), silicon germanium (SiGe), gallium arsenic phosphide (GaAsP), gallium indium phosphide (InGaP), gallium indium arsenide (InGaAs), gallium indium arsenic phosphide (InGaAsP), aluminum indium arsenide (InAlAs), and/or aluminum gallium arsenide (AlGaAs); or (iv) a combination thereof. Further, substrate 104 can be doped depending on design requirements (e.g., p-type substrate or n-type substrate). In some embodiments, substrate 104 can be undoped. In some embodiments, substrate 104 can be doped with p-type dopants (e.g., boron (B), indium (In), aluminum (Al), or gallium (Ga)) or n-type dopants (e.g., phosphorus (P), arsenic (As), or antimony (Sb)). In some embodiments, a crystal orientation of substrate 104 can be (100), (110), or (111). In some embodiments, substrate 104 can include a die, a buffer layer on the die, and an interlayer dielectric with conductive vias and/or conductive lines embedded in the interlayer dielectric. In some embodiments, the conductive vias and/or conductive lines can couple to external electrical components, such as transistors, resistors, capacitors, and inductors. In some embodiments, the electrical components can be included in the interlayer dielectric of substrate 104. In some embodiments, doped layer 112 can be disposed on the interlayer dielectric.

Referring to FIGS. 2A and 2B, substrate 104 can include a die 610, a buffer layer 608 disposed on die 610, and an interlayer dielectric 502 disposed on buffer layer 608. In some embodiments, die 610 can be a semiconductor wafer bonded with interlayer dielectric 502 through buffer layer 508. Die 610 can provide mechanical support to the structure disposed on it. Buffer layer 608 can provide mechanical bonding strength and electrical isolation between interlayer dielectric 502 and die 610 and can include a dielectric material, such as silicon oxide, silicon nitride, any other suitable dielectric material, and/or combinations thereof. Interlayer dielectric 502 can include silicon oxide, silicon nitride, any other suitable dielectric material, and/or combinations thereof. In some embodiments, interlayer dielectric 502 can include transistors 508 electrically coupled to pixels 120 to process charge signals generated by pixels 120 from optical signals. Transistors 508 can include metal-oxide-semiconductor field effect transistors (MOSFETs) fin field effect transistors (fin-FETs), gate-all-around field effect transistors (GAA-FETs), and/or combinations thereof. In some embodiments, transistors 508 can include p-type and/or n-type transistors. In some embodiments, transistors 508 include charge pass transistors, transfer transistors, reset transistors, amplifying transistors, select transistors, source follower transistors, and/or readout transistors. In some embodiments, interlayer dielectric 502 can include interconnect layers that couple transistors 508 with each other and/or to external circuits. The interconnect layers can include conductive vias 504 and conductive lines 506. Conductive vias 504 and conductive lines 506 can include conductive materials, such as copper, aluminum, tungsten, doped polysilicon, any other suitable conductive material, and/or combinations thereof. Other circuits and devices used to detect and process optically-excited charge carriers can also be embedded in interlayer dielectric 502 and are not illustrated for simplicity.

Referring to FIGS. 1A-2B, doped layer 112 can extend along the horizontal directions (the x- and y-axes) between pixels 120 and surrounding lower portions of pixels 120. For example, doped layer 112 can include portions 112x extending along the x-axis and portions 112y extending along the y-axis. It is noted that according to FIGS. 1A and 1B, FIG. 2B shows portions 112y not as a part of the cross section but as viewed in the background, since line A-A′ does not cross portions 112y in FIGS. 1A and 1B. Doped layer 112 can be doped with p-type or n-type dopants to form a depletion region under the array of pixels 120, in order to prevent optically-excited charge carriers from leaking between adjacent pixels 120. In some embodiments, doped layer 112 can include the same elementary semiconductor or the same compound semiconductor as substrate 104. In some embodiments, doped layer 112 can include a semiconductor different from the semiconductor in substrate 104. In some embodiments, doped layer 112 can be doped with p-type dopants (e.g., B, Al, Ga, and/or In) or n-type dopants (e.g., P, As, and/or Sb). In some embodiments, a crystal orientation of doped layer 112 can be (100), (110), or (111). In some embodiments, a doping concentration of doped layer 112 can be between about 1×10¹⁷ cm⁻³ and about 5×10¹⁸ cm⁻³. In some embodiments, a thickness of doped layer 112 can be between about 0.3 μm and about 5 μm. In some embodiments, doped layer 112 can be formed by an ion implantation process. In some embodiments, doped layer 112 can be formed by a diffusion process.

Referring to FIGS. 1A-2B, pixels 120 disposed on substrate 104 can be separated from each other by doped layer 112 and deep trench isolations (DTIs) 142. In some embodiments, the array of pixels 120 can include a number of rows and a number of columns of pixels 120. For example, the array of pixels 120 can include 480 rows and 640 columns, such that a resolution of image sensor device 100 is 480×640. It is noted that according to FIGS. 1A and 1B, FIG. 2B shows pixels 120 not as a part of the cross section but as viewed in the background, since line A-A′ does not cross pixels 120 in FIGS. 1A and 1B. In some embodiments, pixels 120 can have the same shape, such as a rectangular shape having a width W1 and a length L1, as shown in FIGS. 1A and 1B. In some embodiments, pixels 120 can have a square shape with width W1 being equal to length L1. In some embodiments, pixels 120 can have other shapes, such as a round shape, an elliptical shape, a triangle shape, a polygon shape, or any other suitable shape. In some embodiments, pixels 120 can have different shapes. In some embodiments, width W1 can be between about 0.5 μm and about 10 μm. In some embodiments, length L1 can be between about 0.5 μm and about 10 μm.

Pixels 120 include radiation sensing regions that can absorb an incident light and generate optically-excited charge carriers, which can be collected by substrate 104, and can further be transformed into electrical signals and processed by transistors 508 in interlayer dielectric 502. In some embodiments, pixels 120 can include the same elementary semiconductor or the same compound semiconductor as doped layer 112. In some embodiments, each pixel 120 can be doped with both p-type and n-type dopants to form a photodiode structure, such as a PN junction or a PIN junction. In some embodiments, pixels 120 can include pinned layer photodiodes, photogates, reset transistors, source follower transistors, transfer transistors, other suitable structures, and/or combinations thereof. In some embodiments, pixels 120 can be doped by an ion implantation process. In some embodiments, pixels 120 can be doped by a diffusion process.

Referring to FIGS. 1A-2B, DTIs 142 extend along the horizontal directions (e.g., x-axis and y-axis). For example, as shown in FIGS. 1A, 2A and 2B, DTIs 142 can include DTIs 142x separating pixels 120 in different rows and DTIs 142y separating pixels 120 in different columns. In some embodiments, DTIs 142x/142y can have a width W between about 0.03 μm and about 0.5 μm. In some embodiments, a ratio of width W1 to width W can be between about 2 and about 20. DTIs 142 can include intersections 142c, at which DTIs 142x and 142y intersect one another, as shown in FIG. 1A. In some embodiments, DTIs 142 can be formed by etching materials originally between pixels 120, such that pixels 120 can be isolated.

In some embodiments, intersections 142c and DTIs 142x/142y can have different critical dimensions (CDs). For example, the CD of DTIs 142x/142y can be width W, which is less than the CD of intersections 142c evaluated by a width C of a recess of intersections 142c. In some embodiments, a ratio of width C to width W can be between about 1 and about 3. In some embodiments, due to the different CDs between intersections 142c and DTIs 142x/142y, an etching rate in intersections 142c and in DTIs 142x/142y can be different, as it is easier for etchants to access bottoms of intersections 142c than to access bottoms of DTIs 142x/142y, resulting in different depths of intersections 142c and DTI 142x/142y. This is also referred to as the “loading effect.” For example, as shown in FIG. 2A, a depth Dt approximate to a midpoint of a section of DTI 142x/142y between two neighboring intersections 142c can be different from a depth Dc within intersection 142c. In some embodiments, depth Dc and depth Dt can be between about 0.5 μm and about 5 μm. In some embodiments, depth Dc can be greater than depth Dt. For example, depth Dc can be greater than depth Dc by about 0.1 μm to about 0.4 μm. In some embodiments, the loading effect as described above can become more significant for trenches with a higher aspect ratio (AR), which can be defined as a ratio of a depth of the trenches to a CD of the trenches. In some embodiments, the aspect ratio of DTI 142 can be between about 5:1 and about 50:1. For example, the aspect ratio of DTIs 142 can be about 5:1, 10:1, 20:1, 30:1, 40:1, and 50:1.

In some embodiments, the loading effect can impact a profile of a bottom surface of DTIs 142. FIG. 2A shows the cross sectional view of structure 105 along one of DTIs 142x (along the A-A′ line) as shown in FIGS. 1A and 1B, according to some embodiments. FIG. 2A shows bottom surfaces 245x of DTIs 142x, bottom surfaces 245y of DTIs 142y, and bottom surfaces 245c of intersections 142c. As shown in FIG. 2A, bottom surfaces 245c can have a recess. Each bottom surface 245x of DTI 142x includes a center 245xc, which is a midpoint between two adjacent intersections 142c.

Due to the loading effect, it is challenging to form a substantially even profile of the bottom surface of the DTIs. In some embodiments, due to the uneven profile of the bottom surfaces of the DTIs, some portions below the bottom surfaces of the DTIs can be above doped layer 112. Since such portions may not be doped with the proper doping profile as doped layer 112, leakage channels of optically-excited charge carriers in pixels 120 can be formed between neighboring pixels 120 through such portions below the bottom surfaces of the DTIs, compromising a resolution of the array of pixels 120 and the performance of image sensor device 100.

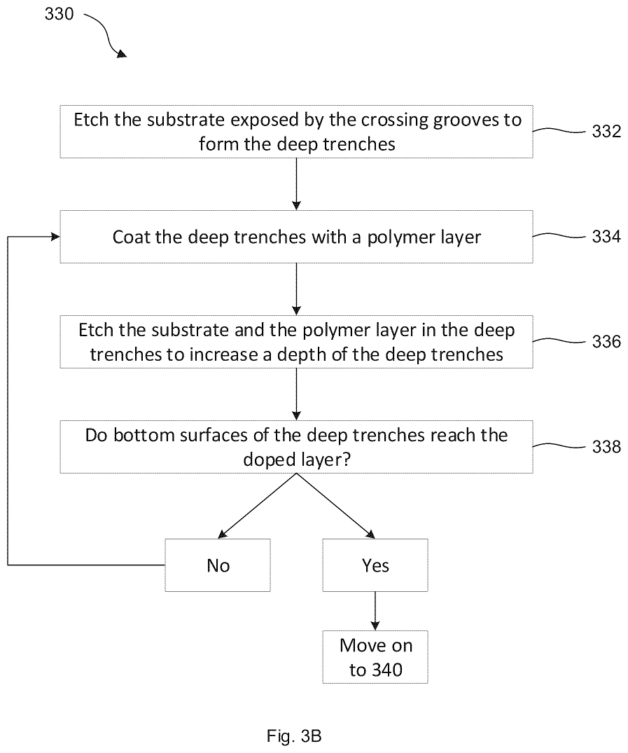

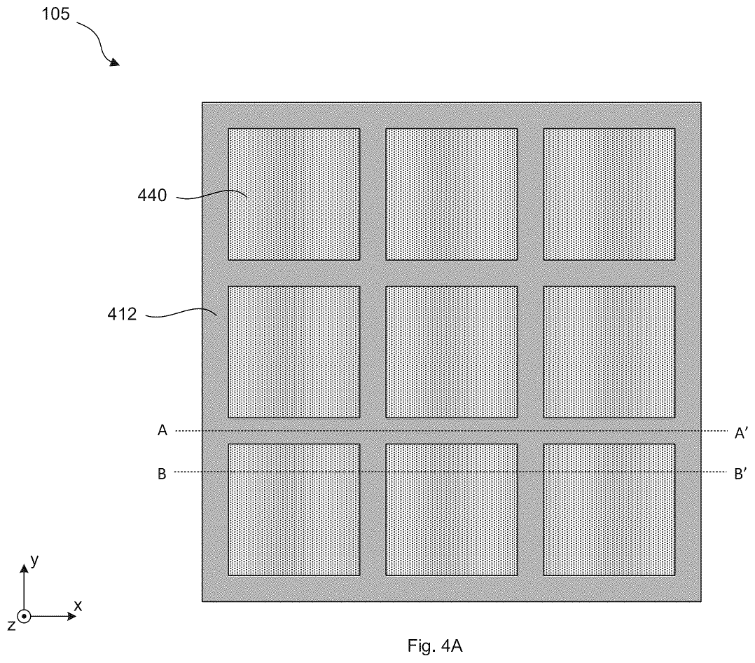

In some embodiments, the loading effect can be mitigated by forming a substantially even profile of bottom surfaces of DTIs 142 between adjacent pixels, as shown in FIG. 2A. In some embodiments, due to the loading effect, bottom surfaces 245c are more susceptible to the higher etching rate in intersections 142c. However, with a method 300 later discussed in FIGS. 3A and 3B, bottom surfaces 245c can be controlled with limited extension into DTI 142x towards center 245xc, such that a profile of bottom surfaces 245x can be maintained to be substantially even. In some embodiments, DTIs 142x/142y can vertically extend sufficiently deep between pixels 120, such that bottom surfaces 245x, 245y and 245c reach doped layer 112, and no portion below the bottom surfaces of DTIs is above doped layer 112 and causing the above issue of leakage current.

In some embodiments, bottom surfaces 245x and 245c can join at a peak 245xp, with a distance r1 between peak 245xp and center 245xc greater than a distance r2 between peak 245xp and a closest side surface 120s of pixel 120, as shown in FIG. 2A. The position of peak 245xp can be considered as a boundary between adjacent bottom surfaces 245x and 245c or an edge of them. In some embodiments, a ratio of distance r1 to distance r2 can be greater than 2:1. In some embodiments, peak 245xp is formed because a position of center 245xc is below a position of peak 245xp, such that bottom surface 245x has a concave curvature, and center 245xc can be a minimum of bottom surfaces 245x, as shown in FIG. 2A. In some embodiments, a vertical distance t1 between center 245xc and peak 245xp can be between about 0 nm and about 100 nm. In some embodiments, distance t1 can be about 0 nm, such that peak 245xp is not prominent, or bottom surfaces 245x is substantially flat. For example, a variation of bottom surfaces 245x can be less than 50 nm. In some embodiments, a vertical distance t2 between center 245xc and a minimum of bottom surface 245c can be between about 300 nm and about 700 nm. In some embodiments, a vertical distance t1+t2 between peak 245xp and center 245xc can be between about 300 nm and about 800 nm. In some embodiments, a maximum gradient of bottom surfaces 245x, as quantified by an angle α, can be less than a maximum gradient of bottom surfaces 245c, as quantified by an angle β. In some embodiments, angle α can be between about 0° and about 30°. In some embodiments, angle β can be between about 50° and about 90°. Similarly, a profile of bottom surfaces 245y can be the same as or similar to the profile of bottom surfaces 245x.

Referring to FIGS. 1A-2B, in some embodiments, structure 105 can further include gap fill 162 over side surface 120s and top surfaces 120t of pixels 120 and filling DTIs 142. In some embodiments, gap fill 162 can extend to bottom surfaces 245x/245y of DTIs 142x/142y and bottom surfaces 245c of intersections 142c. In some embodiments, due to the recess of bottom surfaces 245c, gap fill 162 can include a portion in the recess and protruding into doped layer 112. In some embodiments, gap fill 162 can include a dielectric material, such as silicon oxide, silicon nitride, any other suitable dielectric material, and/or combinations thereof. Structure 105 can further include a buffer layer 264 on gap fill 162. Buffer layer 264 can include a dielectric material the same as or different from that of gap fill 162. In some embodiments, structure 105 can further include filters 268 and micro-lenses 270 on buffer layer 264. In some embodiments, each of filters 268 and micro-lenses 270 can be vertically aligned above one of the pixels 120. In some embodiments, adjacent filters 268 can be separated by grid structures 266. In some embodiments, filters 268 can include color filters, such as color filters for red, blue, and/or green lights. In some embodiments, filters 268 can include filters for non-visible lights, such as infrared and/or ultraviolet lights. In some embodiments, micro-lenses 270 can be configured to focus the incident light towards pixels 120.

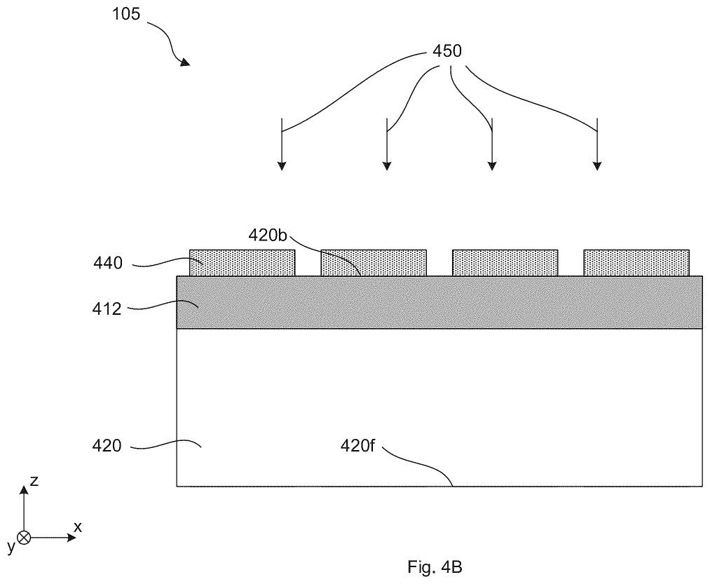

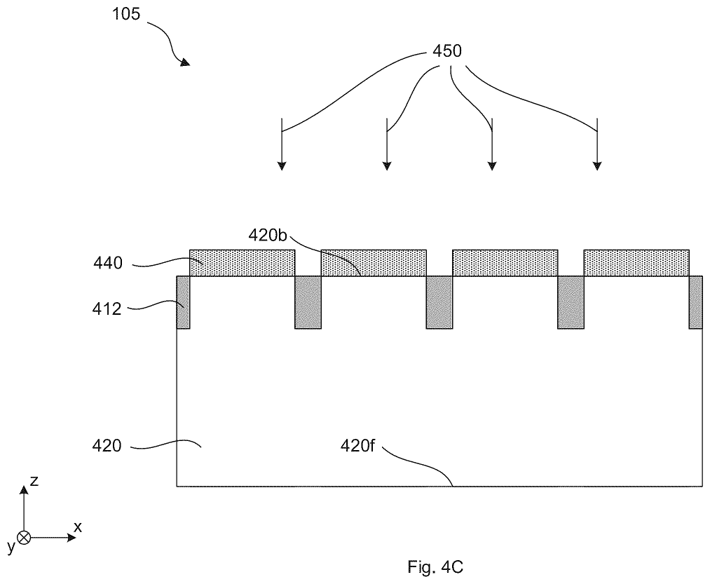

According to some embodiments, FIGS. 3A and 3B illustrate a flowchart of a method 300 for forming structure 105 as shown in FIGS. 1A-2B. This disclosure is not limited to this operational description and additional operations may be performed. Other operations can be performed between the various operations of method 300 and are omitted merely for clarity. Moreover, not all operations may be needed to perform the disclosure provided herein. Additionally, some of the operations may be performed simultaneously, or in a different order than the ones shown in FIGS. 3A and 3B. In some embodiments, one or more other operations may be performed in addition to or in place of the presently described operations. For illustrative purposes, method 300 is described with reference to intermediate structures shown in FIGS. 4A-13. The discussion of elements in FIGS. 1A-2B with the same annotations applies to FIGS. 4A-13, unless mentioned otherwise.

Referring to FIG. 3A, method 300 begins with operation 310, in which a doped layer is formed in a substrate, as described with reference to FIGS. 4A-6. FIG. 4A is a top view of partially-fabricated structure 105. FIGS. 4B, 5, and 6 are cross-sectional views (along the A-A′ line in FIG. 4A) of partially-fabricated structure 105. FIG. 4C is a cross-sectional view (along the B-B′ line in FIG. 4A) of partially-fabricated structure 105. Structure 105 at this stage of method 300 can include a substrate 420 having first and second surfaces 420b and 420f opposite to each other and a doped layer 412 disposed on substrate 420. For example, as shown in FIGS. 4A-4C, a patterned mask 440 can be formed on first surface 420b of substrate 420, and doped layer 412 can be formed by an ion implantation method, during which dopants 450 can be implanted into portions of first surface 420b exposed by patterned mask 440, such that a portion of substrate 420 under first surface 420b can be doped and turned into doped layer 412. It is noted that according to FIG. 4A, FIG. 4B shows patterned mask 440 not as a part of the cross section but as viewed in the background. In some embodiments, dopants 450 can include p-type dopants (e.g., B, Al, Ga, and/or In) or n-type dopants (e.g., P, As, and/or Sb). For example, dopants 450 can include B. In some embodiments, an implantation energy of dopants 450 can be between about 40 keV and about 80 keV to control a thickness of doped layer 412 to be between about 0.3 μm and about 5 μm. In some embodiments, an implantation dose of dopants 450 can be between about 1×10¹³ cm⁻² and about 2.5×10¹⁵ cm⁻² to control the dopant concentration of doped layer 412 to be between about 1×10¹⁷ cm⁻³ and about 5×10¹⁸ cm⁻³.

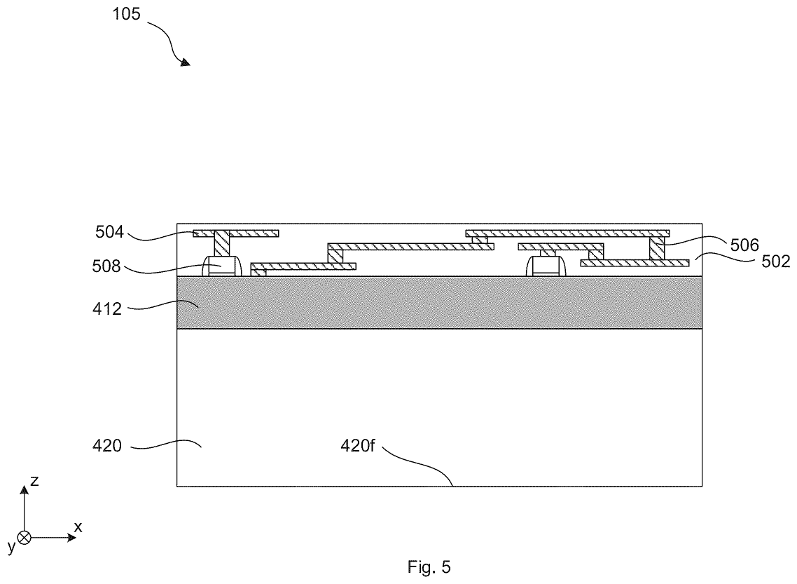

In some embodiments, operation 310 can further include forming an interlayer dielectric 502 on doped layer 412 and forming interconnect layers in interlayer dielectric 502, as shown in FIG. 5. Interlayer dielectric 502 can be formed by depositing a dielectric material on doped layer 412. In some embodiments, interlayer dielectric 502 can include silicon oxide, silicon nitride, any other suitable dielectric material, and/or combinations thereof. In some embodiments, forming transistors 508 can be formed in interlayer dielectric 502 and on doped layer 412. In some embodiments, conductive vias 504 and conductive lines 506 can be formed in interlayer dielectric 502 to electrically couple transistors 508. Conductive vias 504 and conductive lines 506 can be formed of conductive materials, such as copper, aluminum, tungsten, doped polysilicon, any other suitable conductive material, and/or combinations thereof. The interconnect layers can be electrically coupled to pixels to be formed in subsequent operations. Other circuits and devices used to detect and process optically-excited charge carriers can also be embedded in interlayer dielectric 502 and are not illustrated for simplicity.

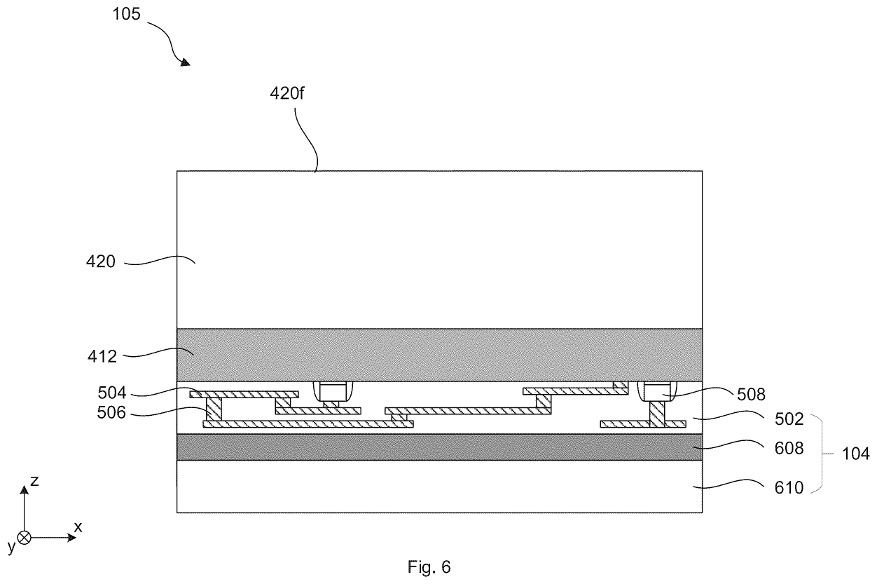

In some embodiments, operation 310 can further include forming a buffer layer 608 on interlayer dielectric 502 and forming die 610 on buffer layer 608, as shown in FIG. 6. Note that structure 105 as shown in FIG. 6 with second surface 420f facing along the z+ direction has been flipped up-side-down with respect to structure 105 as shown in FIG. 5, in which second surface 420f faces along the z-direction. Interlayer dielectric 502, buffer layer 608, and die 610 together compose substrate 104 as shown in FIGS. 1A-2B. Buffer layer 608 can be formed by depositing a dielectric material, such as silicon oxide, silicon nitride, any other suitable dielectric material, and/or combinations thereof. Buffer layer 608 can be formed by suitable deposition methods, such as chemical vapor deposition (CVD), plasma-enhanced CVD (PECVD), atomic layer deposition (ALD), physical vapor deposition (PVD), any other suitable process, and/or combinations thereof. Buffer layer 608 can be planarized to form a smooth surface by a planarization process (e.g., a chemical mechanical polishing process). In some embodiments, buffer layer 608 provides electrical isolation between Interlayer dielectric 502 and die 610. In some embodiments, die 610 can be bonded onto interlayer dielectric 602 through buffer layer 608 by a suitable wafer bonding method, such as fusion bonding, anodic bonding, direct bonding, any other suitable bonding process, and/or combinations thereof. Die 610 provides mechanical support to the partially-fabricated image sensor device so that processes on a second surface 420f can be performed. In some embodiments, die 610 can be formed using a material similar to substrate 420. For example, die 610 includes a silicon material. In some embodiments, die 610 can include a glass substrate.

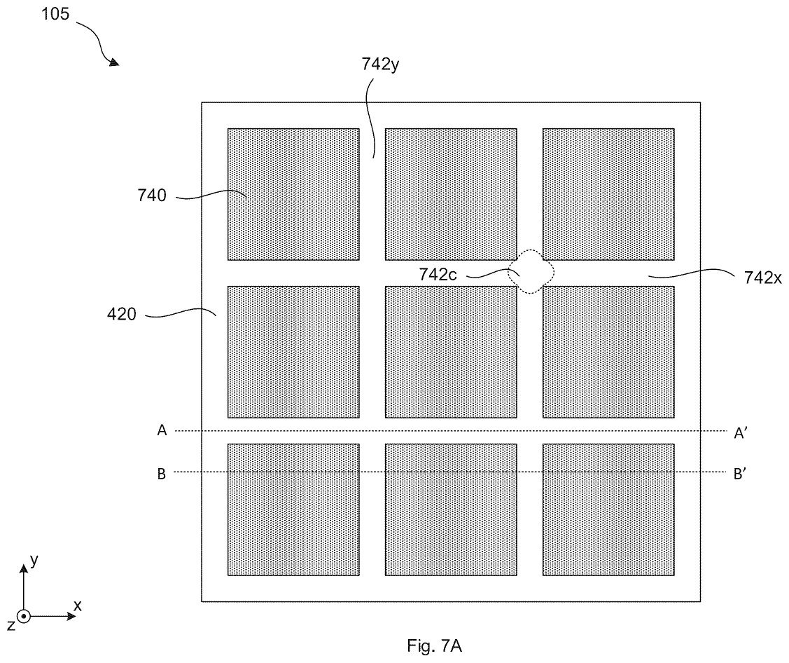

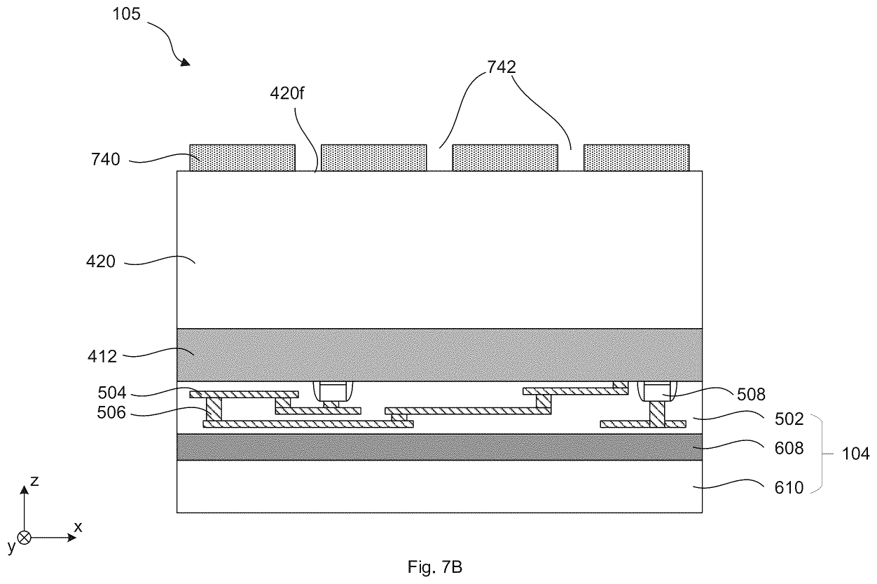

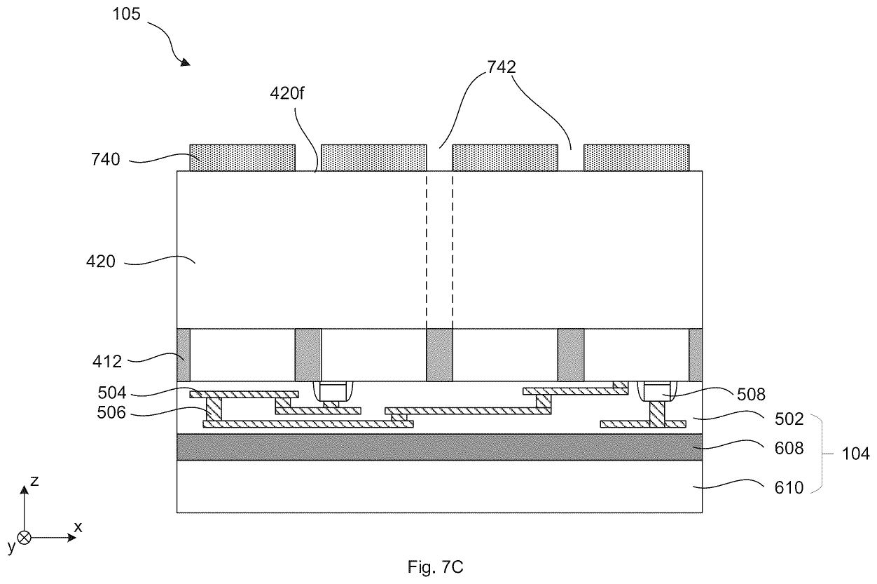

Referring to FIG. 3A, method 300 continues with operation 320 and the process of forming a patterned mask layer on the substrate with crossing grooves, as described with reference to FIGS. 7A-7C. FIG. 7A is a top view of partially-fabricated structure 105. FIG. 7B is a cross-sectional view (along the A-A′ line in FIG. 7A) of partially-fabricated structure 105. FIG. 7C is a cross-sectional view (along the B-B′ line in FIG. 7A) of partially-fabricated structure 105. For example, a mask layer 740 can be formed on second surface 420f of substrate 420. Mask layer 740 can be patterned with openings 742 to expose portions of second surface 420f to be etched in subsequent operations to form DTIs. In particular, mask layer 740 has a pattern the same as that of patterned mask 440 as shown in FIGS. 4A-4C, and openings 742 are aligned with doped layer 412, as shown by vertical dashed lines in FIG. 7C, such that the DTIs formed in the subsequent operations can be aligned with doped layer 412. It is noted that according to FIG. 7A, FIG. 7B shows patterned mask 440 not as a part of the cross section but as viewed in the background. As shown in FIGS. 7A-7C, openings 742 include grooves 742x extending along the x-axis and grooves 742y extending along the y-axis, defining the positions of DTIs 142x and 142y as shown in FIGS. 1A-2B. Similarly, intersections 742c of grooves 742x and 742y define intersections 142c. Accordingly, other portions of second surface 420f covered by mask layer 740 define pixels 120.

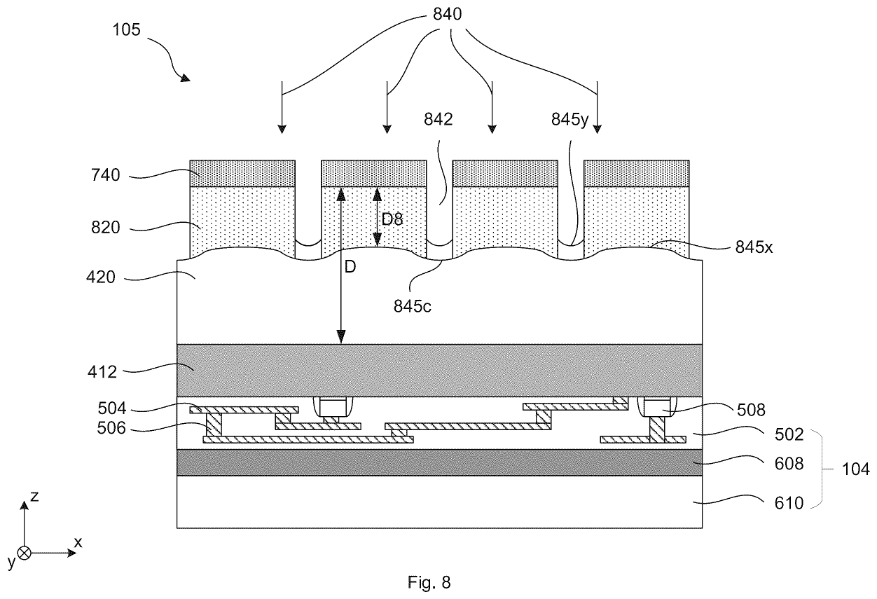

Referring to FIG. 3A, method 300 continues with operation 330 and the process of forming DTIs in the substrate according to the patterned mask layer, as described with reference to FIGS. 8-12, which are cross-sectional views (corresponding to the A-A′ line in FIG. 7A) of partially-fabricated structure 105. In some embodiments, operation 330 can form DTIs with a substantially even profile of bottom surface as shown in FIG. 2. Operation 330 is further elaborated in FIG. 3B.

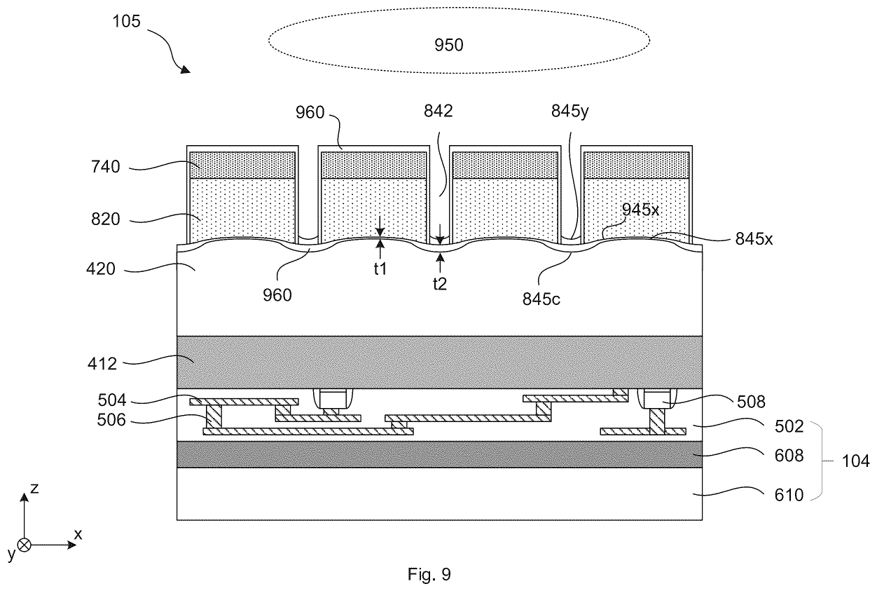

Referring to FIG. 3B, operation 330 starts with operation 332 and the process of etching the substrate exposed by the crossing grooves, as described with reference to FIG. 8. For example, etchants 840 can be applied to etch portions of substrate 420 exposed by grooves 742x and 742y to form DTIs 842 and pixels 820. It is noted that according to FIG. 7A, FIG. 8 (so as the subsequent FIGS. 9-13) shows pixels 820 not as a part of the cross section but as viewed in the background. In some embodiments, etchants 840 can include reactive plasma in a reactive ion etching process. In some embodiments, the etching can be anisotropic etching, in which an etching rate along a vertical direction (e.g., the z-axis) is greater than an etching rate along a horizontal direction (e.g., the x-axis or the y axis), such that the etching process is faster towards bottom surfaces of the DTIs 842 than towards side surfaces of DTIs 842. In some embodiments, the substrate can be biased with a voltage during the etching process. For example, substrate 420 can be biased with a voltage between about 100 V and about 400 V. In some embodiments, an etching power of etchants can be between about 500 W and about 1500 W. In some embodiments, due to the loading effect, bottom surfaces 845c corresponding to intersections 742c can be etched at a greater etching rate compared to bottom surfaces 845x/845y corresponding to grooves 745x/745y, since it is easier for etchants 840 to reach bottom surfaces 845c than to reach bottom surfaces 845x/845y due to the greater CD of intersections 742c. In some embodiments, due to the loading effect, bottom surfaces 845c can have recesses with concave curvatures, and bottom surfaces 845x/845y can have convex curvatures. In some embodiments, before the convex curvatures of bottom surfaces 845x/845y become significant, the etching process of operation 332 can stop. For example, when a depth D8 of bottom surfaces 845x reaches a certain value, the etching process of operation 332 can stop. In some embodiments, a ratio of depth D8 to a distance D between top surfaces of pixels 820 and doped layer 412 can be between about 0.1 and about 0.5. For example, the ratio of depth D8 to distance D can be between about 0.1 and about 0.2, between about 0.2 and about 0.3, between about 0.3 and about 0.4, and between about 0.4 and about 0.5.

Referring to FIG. 3B, operation 330 continues with operation 334 and the process of coating the DTIs with a polymer layer, as described with reference to FIG. 9. For example, a polymer layer 960 can be deposited on bottom surfaces 845x/845y and 845c as well as on side surfaces of DTIs 842. In some embodiments, depositing polymer layer 960 can include providing a gas 950 of a polymer material. In some embodiments, gas 950 can include a fluorocarbon (CₓF_{y}), hydrofluorocarbons (CₓH_{y}F_{z}), sulphur fluoride (SₓF_{y}), hydrogen bromide (HₓBr_{y}), or a combination thereof. In some embodiments, gas 950 can include C₄F₈ at a flowrate between about 10 sccm and about 100 sccm. In some embodiments, gas 950 can include SF₆ at a flowrate between about 100 sccm and about 600 sccm. Similar to the loading effect in operation 332, in which bottom surfaces 845c are more accessible to etchants 840 than bottom surfaces 845x/845y due to the greater CD of bottom surfaces 845c, bottom surfaces 845c in operation 334 are also more accessible to gas 950 than bottom surfaces 845x/845y, resulting in deposited polymer layer 960 having a greater thickness on bottom surfaces 845c than on bottom surfaces 845x/845y. For example, as shown in FIG. 9, a thickness t1 of polymer layer 960 at a first position at a midpoint of a section of bottom surface 845x between two neighboring DTIs extending along the y-axis can be less than a thickness t2 of polymer layer 960 at a second position in bottom surface 845c, and the thickness increases monotonically from the first position to the second position. In some embodiments, the uneven thickness of polymer layer 960 on bottom surfaces 845x can compensate or balance the convex curvature of bottom surfaces 845x, such that surfaces 945x of polymer layer 960 on bottom surfaces 845x can have a less convex curvature. In some embodiments, surfaces 945x can be substantially even. In some embodiments, surfaces 945x can have a concave curvature. The condition of the curvature of surfaces 945x can be controlled by controlling deposition conditions (e.g., a deposition rate and/or a deposition time) of polymer layer 960. In some embodiments, with a greater deposition rate and a longer deposition time, the curvature of surfaces 945x can change from a convex curvature to being substantially flat to a concave curvature. In some embodiments, the coating process of operation 334 can stop when the curvature of surfaces 945x reaches a condition that compensates or balances the convex curvature of bottom surfaces 845x.

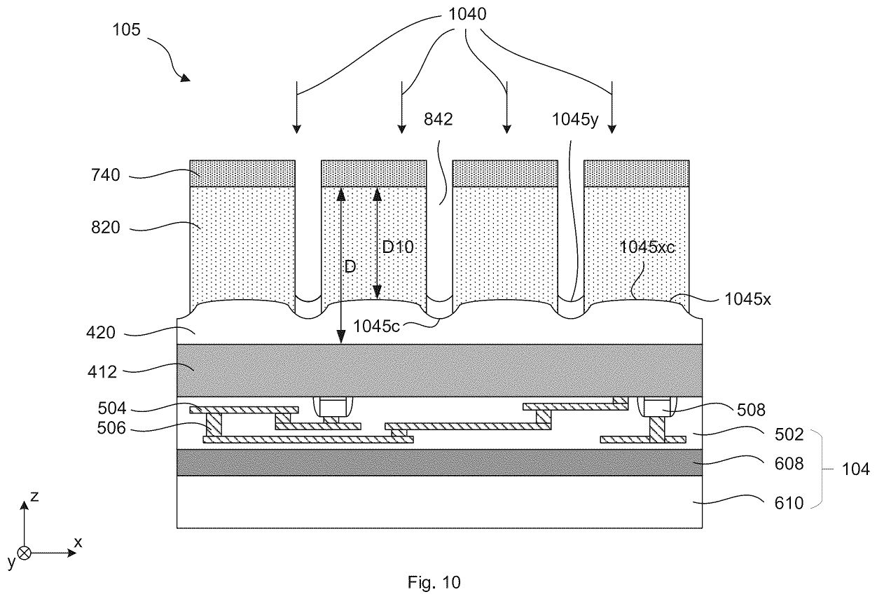

Referring to FIG. 3B, operation 330 continues with operation 336 and the process of etching the polymer layer and the substrate to increase a depth of the DTIs, as described with reference to FIG. 10. For example, etchants 1040 can be applied to etch polymer layer 960 and portions of substrate 420 to increase the depth of DTIs 842 and the heights of pixels 820. In some embodiments, etchants 1040 can be the same as or similar to etchants 840, and description of the etching process of operation 332 applies to operation 334, unless mentioned otherwise. During operation 334, bottom surfaces 1045x and 1045y of DTIs 842 are formed extending along the x-axis and the y-axis, respectively. Bottom surfaces 1045c at intersections of bottom surfaces 1045x and 1045y are also formed. In some embodiments, due to the thickness profile of polymer layer 960 formed in operation 334, etchants 1040 in operation 336 can etch bottom surfaces 1045x and 1045y to form more even profiles compared to those of bottom surfaces 845x and 845y as shown in FIG. 8. For example, in spite of the loading effect, etchants 1040 can etch a greater thickness into substrate 420 at a location around a midpoint 1045xc, after etching a thinner layer of polymer layer 960 on the location compared to locations away from midpoint 1045xc and covered with a thicker layer of polymer layer 960. Overall, bottom surfaces 1045x and 1045y can be etched to have a profile more even than bottom surfaces 845x and 845y as shown in FIG. 8. For example, bottom surfaces 1045x and 1045y can have a convex curvature less than the convex curvature of bottom surfaces 845x and 845y. In another example, bottom surfaces 1045x and 1045y can be substantially flat. In a third example, bottom surfaces 1045x and 1045y can have a concave curvature. In some embodiments, the etching process of operation 336 can stop when a depth D10 of bottom surfaces 1045x reaches a certain value. In some embodiments, a ratio between depth D10 and distance D can be between about 0.2 and about 0.7. For example, the ratio between depth D10 and distance D can be between about 0.2 and about 0.3, between about 0.3 and about 0.5, and between about 0.5 and about 0.7.

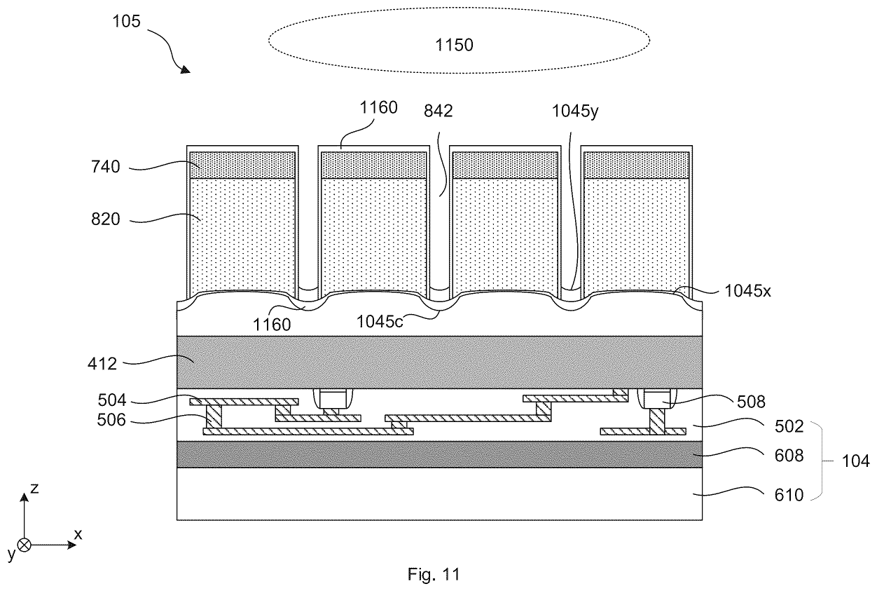

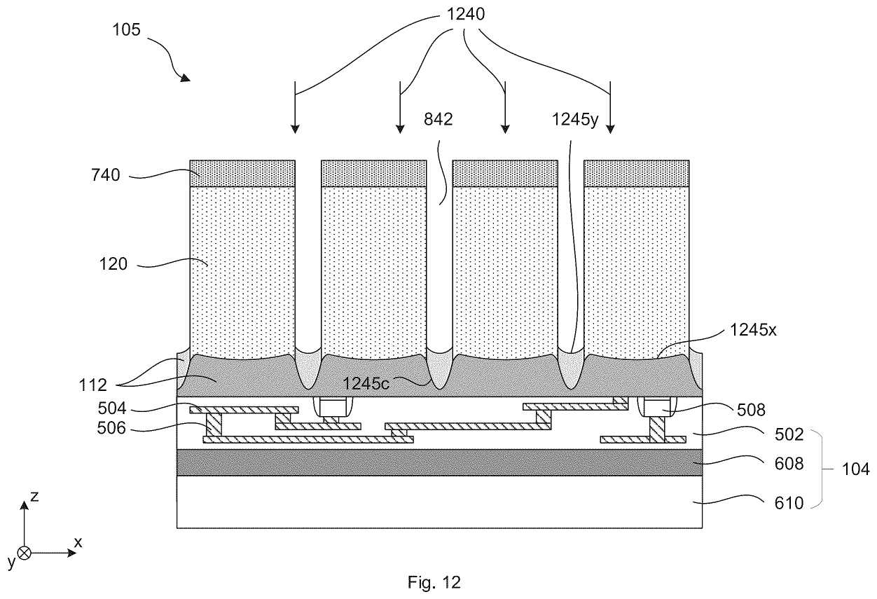

Referring to FIG. 3B, operation 330 continues with operation 338 to determine if a depth of the DTIs is sufficient such that bottom surfaces of the DTIs reach the doped layer. As discussed with reference to FIGS. 1A-2B, if the bottom surfaces of the DTIs are not entirely etched into the doped layer, optically-excited charge carriers between pixels can leak and compromise the performance of image sensor device 100. Therefore, if the answer to the question in operation 338 is ‘No’, operation 330 proceeds by repeating operation 334 and the process of coating the DTIs with a polymer layer, as described with reference to FIG. 11. For example, a polymer layer 1160 can be deposited on bottom surfaces 1045x/1045y and 1045c as well as on side surfaces of DTIs 842. In some embodiments, depositing polymer layer 1160 can include providing a gas 1150 of a polymer material. The description of depositing polymer layer 960 as described with reference to FIG. 9 applies to the deposition of polymer layer 1160. Operation 330 then continues with operation 336 and the process of etching the polymer layer and the substrate to increase a depth of the DTIs, as described with reference to FIG. 12. For example, etchants 1240 can be applied to etch polymer layer 1160 and portions of substrate 420 to increase the depth of DTIs 842 and the height of pixels 820. In some embodiments, etchants 1240 can be the same as etchant 1040. In some embodiments, the coating process in operation 334 and the etching process in operation 336 can be alternatingly repeated multiple times (e.g., 2 to 5 times), until the answer to the question in operation 338 is ‘Yes’. If ‘Yes’, an entirety of bottom surfaces 1245x/1245y and 1245c of DTIs 842 has been etched into doped layer 412, as shown in FIG. 12, and pixels 120 are formed to be immune to charge carrier leakage. Operation 330 can then be finished with a removal process to remove mask layer 740.

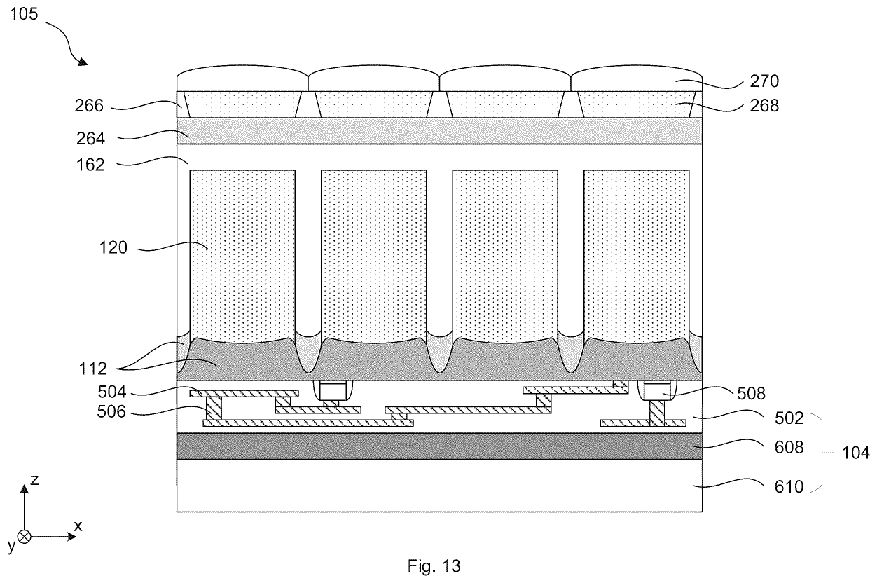

Referring to FIG. 3A, method 300 continues with operation 340 and the process of filling the DTIs with a dielectric material and forming filters and micro-lenses, as described with reference to FIG. 13. FIG. 13 is a cross-sectional view of structure 105, in accordance with some embodiments. In some embodiments, forming the image sensing pixels can include forming gap fill 162, buffer layer 264, grid structures 266, color filters 268, and micro-lenses 270.

Gap fill 162 is formed over pixels 120 by a blanket deposition followed by a planarization process. Gap fill 162 fills DTIs 842. Gap fill 162 can be formed using any suitable dielectric material, such as silicon oxide, silicon nitride, any other suitable dielectric material, and/or combinations thereof. In some embodiments, a liner layer (not shown) is formed between pixels 120 and gap fill 162. The liner layer can be formed using a high-k dielectric material, such as hafnium oxide (HfO₂), tantalum pentoxide (Ta₂O₅), zirconium dioxide (ZrO₂), aluminum oxide (Al₂O₃), other high-k material, and/or combinations thereof. The material for gap fill 162 can be deposited using any suitable deposition method, such as atomic layer deposition (ALD), molecular beam epitaxy (MBE), high density plasma CVD (HDPCVD), metal organic (MOCVD), remote plasma CVD (RPCVD), plasma-enhanced CVD (PECVD), plating, any other suitable method, and/or combinations thereof. After gap fill material is deposited, a planarization process, such as a chemical mechanical polishing process is performed on the deposited gap fill material to form a planar top surface of gap fill 162. In some embodiments, gap fill 162 is deposited into DTIs 842 to prevent crosstalk between pixels 120.

In some embodiments, a buffer layer 264 can be formed on the top surface of gap fill 162. A buffer material is blanket deposited followed by a planarization process to form buffer layer 264 and provide a planar top surface for one or more subsequent fabrication processes. In some embodiments, buffer layer 264 can be the same dielectric material as gap fill 162. In some embodiments, buffer layer 264 be a different dielectric material.

Grid structures 266 are formed on buffer layer 264. In some embodiments, grid structures 266 can be formed by depositing a metal layer on buffer layer 264 and performing a patterning process. Grid structures 266 can be used for reducing crosstalk between pixels (e.g., between adjacent pixels) and can include a metal grid used to reflect light towards corresponding pixels 120. In some embodiments, grid structures 266 are formed using metal, such as copper, tungsten, aluminum, any other suitable metal, and/or combinations thereof. In some embodiments, grid structures 266 are formed using any material that has a high reflective property. In some embodiments, grid structures 266 can have a stacked structure, in which additional dielectric grid structures are formed on grid structures 266. In some embodiments, each of grid structures 266 can have a height of about 200 nm to about 300 nm (e.g., 200 nm to 300 nm). For example, grid structure 266 can have a height of about 250 nm.

Color filters 268 can be formed on buffer layer 264 and between grid structures 266. Micro-lenses 270 can be formed over color filters 268 and grid structures 266. Each of the micro-lenses 270 and color filters 268 can be formed to vertically align with one of pixels 120.

Pixels 120 are configured to sense radiation (or radiation waves), such as an incident light that is projected towards micro-lenses 270. The incident light enters the image sensor device 100 through the back surface and can be detected by one or more of the pixels 120. In some embodiments, in addition to detecting visible light, image sensor device 100 can also be used to detect non-visible light due to the increased depth of grooved semiconductor material and reduced crosstalk between pixels.

The embodiments described herein are directed to a structure of a semiconductor image sensor device and a method of forming the structure. In some embodiments, the structure can include image sensing pixels with a small critical dimension (CD) and separated by deep trench isolations (DTIs) with a high aspect ratio (AR). In some embodiments, sections of the DTIs between adjacent image sensing pixels can have an even bottom surface profile to prevent leakage of optically-excited charge carriers between the image sensing pixels. In some embodiments, the method can include performing an etching process and a coating process to mitigate loading effects. In some embodiments, the etching process and the coating process can be alternatingly repeated until bottom surfaces of the DTIs are etched into a doped layer under the image sensing pixels.

In some embodiments, a method includes forming a doped layer in a substrate and forming a mask on the substrate. The mask can be patterned with first and second grooves intersecting with each other and exposing a top surface of the substrate. The method can further include forming first and second trenches in the substrate according to the mask. Forming the first and second trenches includes etching the substrate, depositing a polymer layer in the first and second trenches, forming bottom surfaces of the first and second trenches below a top surface of the doped layer, and forming a recess at a crossing of the first and second trenches. A bottom surface of the recess is below the bottom surfaces of the first and second trenches. An edge of the recess is higher than the bottom surfaces of the first and second trenches.

In some embodiments, a method includes forming a doped layer in a substrate, etching the substrate to form first and second trenches, depositing a polymer layer in the first and second trenches, increasing a depth of the first and second trenches by etching the polymer layer and a portion of the substrate in the first and second trenches until the depth is greater than a distance between the doped layer and a top surface of the substrate, and forming a recess at an intersection of the first and second trenches while increasing the depth of the first and second trenches. An edge of the recess is above a bottom surface of the first and second trenches.

In some embodiments, a structure includes a doped layer on a substrate, first, second, third, and fourth radiation sensing regions on the substrate and with their lower portions surrounded by the doped layer, and first and second trenches crossing each other and separating the first, second, third, and fourth radiation sensing regions. Bottom surfaces of the first and second trenches are below a top surface of the doped layer. The structure can further include a recess at an intersection of the first and second trenches. A bottom surface of the recess is below the bottom surfaces of the first and second trenches. An edge of the recess is above the bottom surfaces of the first and second trenches.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a doped layer in a substrate;
forming a mask on the substrate, wherein the mask comprises first and second grooves intersecting with each other and exposing a top surface of the substrate; and
forming first and second trenches in the substrate according to the mask, wherein forming the first and second trenches comprises:
etching the substrate;
depositing a polymer layer in the first and second trenches;
forming bottom surfaces of the first and second trenches below a top surface of the doped layer; and
forming a recess at a crossing of the first and second trenches, wherein a bottom surface of the recess is below the bottom surfaces of the first and second trenches, and wherein an edge of the recess is higher than the bottom surfaces of the first and second trenches.

2. The method of claim 1, wherein depositing the polymer layer comprises:
depositing a first portion of the polymer layer at the bottom surfaces of the first and second trenches at a first deposition rate; and
depositing a second portion of the polymer layer in the recess at a second deposition rate greater than the first deposition rate.

3. The method of claim 1, wherein depositing the polymer layer comprises:
depositing a first portion of the polymer layer at the bottom surface of the first trench at a first deposition rate; and
depositing a second portion of the polymer layer at the bottom surface of the first trench at a second deposition rate greater than the first deposition rate, wherein the second portion is between the first portion and the recess.

4. The method of claim 1, wherein depositing the polymer layer comprises depositing fluorocarbon (CₓF_{y}), hydrofluorocarbons (CₓH_{y}F_{z}), sulphur fluoride (SₓF_{y}), or hydrogen bromide (HₓBr_{y}).

5. The method of claim 1, wherein forming the first and second trenches comprises forming the first and second trenches having an aspect ratio between about 5 and about 50.

6. The method of claim 1, wherein forming the first and second trenches comprises forming the first and second trenches with a depth between about 0.5 μm and about 5 μm.

7. The method of claim 1, wherein:
forming the recess comprises forming the recess having a first width; and
forming the first and second trenches comprises forming the first and second trenches having a second width, wherein a ratio of the first width to the second width is between about 1 and about 3.

8. A method, comprising:
forming a doped layer in a substrate;
etching the substrate to form first and second trenches;
depositing a polymer layer in the first and second trenches;
increasing a depth of the first and second trenches until the depth is greater than a distance between the doped layer and a top surface of the substrate, wherein increasing the depth comprises etching the polymer layer and a portion of the substrate in the first and second trenches; and
forming a recess at an intersection of the first and second trenches while increasing the depth of the first and second trenches, wherein an edge of the recess is above a bottom surface of the first and second trenches.

9. The method of claim 8, further comprising forming a third trench crossing the first trench and parallel to the second trench, wherein a ratio of a distance between the second and third trenches to a width of the second trench is between about 2 and about 10.

10. The method of claim 9, wherein the distance between the second and third trenches is between about 0.5 μm and about 5 μm.

11. The method of claim 9, further comprising forming an other recess at an intersection of the first and third trenches, wherein a distance between the recess and the other recess is less than the distance between the second and third trenches.

12. The method of claim 8, wherein forming the recess comprises forming a side surface of the recess, and wherein an angle between the side surface of the recess and the top surface of the substrate is between about 50° and about 90°.

13. The method of claim 8, wherein etching the polymer layer comprises etching a first portion of the polymer layer in the recess at a first rate and etching a second portion of the polymer layer in the first and second trenches at a second rate less than the first rate.

14. The method of claim 8, wherein forming the doped layer comprises performing an ion implantation process on a back surface of the substrate.

15. A structure, comprising:
a doped layer on a substrate;
first, second, third, and fourth radiation sensing regions on the substrate, wherein lower portions of the first, second, third, and fourth radiation sensing regions are surrounded by the doped layer;
first and second trenches crossing each other and separating the first, second, third, and fourth radiation sensing regions, wherein the first and second trenches extend vertically to a top surface of the doped layer; and
a dielectric layer filling the first and second trenches and having a portion protruding into the doped layer, wherein the portion is at an intersection of the first and second trenches.

16. The structure of claim 15, wherein an angle between a side surface of the portion of the dielectric layer and the top surface of the substrate is between about 50° and about 90°.

17. The structure of claim 15, wherein a ratio of a width of the first radiation sensing region to a width of the first trench is between about 2 and about 10.

18. The structure of claim 15, wherein a vertical difference between a bottom surface of the first trench and the bottom surface of the portion of the dielectric layer is between about 300 nm and about 800 nm.

19. The structure of claim 15, wherein an aspect ratio of the first and second trenches is between about 10 and about 50.

20. The structure of claim 15, wherein a variation of a bottom surface of the first trench is less than about 50 nm.
